(19) United States
(12) Patent Application Publication
(10) Pub. No.: US 2008/0035985 A1
(43) Pub. Date: Feb. 14, 2008

(54) Semiconductor device and method of manufacturing the same

(75) Inventors: Satoshi Shimizu, Tokyo (JP); Yoshihiro Ikeda, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/882,164

(22) Filed: Jul. 31, 2007

(30) Foreign Application Priority Data
Aug. 11, 2006 (JP) 2006-220062 (P)

(51) Int. Cl. H01L 29/788; H01L 21/31

(52) U.S. Cl. 257/316; 438/778; 257/E29.3; 257/E21.24

(57) ABSTRACT

The semiconductor device which is hard to generate malfunction and whose reliability of an element is high, and its manufacturing method are offered.

Each of a plurality of convex patterns is formed on the front surface of a semiconductor substrate so that it may have a floating gate and a control gate. The insulating layer has covered the side surface and the upper surface of a plurality of convex patterns, and the bottom between convex patterns. A contact interlayer insulating layer covers the cavity part located via an insulating layer between a plurality of convex patterns and on a plurality of convex patterns, and has a through hole. An insulating layer closes a through hole and occludes the cavity part.

### CROSS-REFERENCE TO RELATED APPLICATION

The present application claims priority from Japanese patent application No. 2006-220062 filed on Aug. 11, 2006, the content of which is hereby incorporated by reference into this application.

### FIELD OF THE INVENTION

The present invention relates to a semiconductor device and its manufacturing method, and particularly relates to the semiconductor device which has a cavity part between gates, and its manufacturing method.

### DESCRIPTION OF THE BACKGROUND ART

From the former, a miniaturization and microfabrication of the semiconductor memory device are advanced. How to make it small without causing various trouble has been an important problem.

And in order to solve the above-mentioned problem in recent years, the AG-AND (Assist Gate-AND) type flash memory provided with a plurality of Assist Gate's for forming an inversion layer in the main surface side of a semiconductor substrate, a floating gate formed between this Assist Gate's, and a control gate formed on this floating gate is proposed (for example, refer to Patent Reference 1).

The manufacturing method of this AG-AND type flash memory is provided with a step which forms Assist Gate on the main surface of a semiconductor substrate, a step which forms an insulating film so that this Assist Gate may be covered, a step which performs dry etching to this insulating film, and a sidewall is formed on the both side surfaces of Assist Gate, and exposes the main surface of a semiconductor substrate located between sidewalls, a step which grows up an insulating film and forms the tunnel insulating film of a floating gate on the main surface of the semiconductor substrate located between this sidewall, and a step which fills up the recess between this sidewall with an electric conduction film, and forms a floating gate.

However, in the structure of the above flash memories, it fills up with the insulating layer between floating gates. For this reason, when microfabrication is advanced, the gap of floating gates becomes narrow and the capacitance between floating gates increases. When the charge quantity accumulated into the floating gate of the memory cell which adjoined by this the memory cell chosen on the occasion of read operation is changed, there was a problem of the, so-called threshold value voltage Vth shift to which the threshold value voltage of the selected memory cell is changed having occurred, and becoming easy to generate malfunction.

On the other hand, the technology of decreasing the capacitance between wirings substantially is proposed by forming a cavity part between wirings rather than embedding an insulator between wirings (for example, refer to Patent Reference 2).

With this technology, after a wiring is formed so that the width of a surface part may be wide and lower width may become narrow in the section form of a wiring, a thick silicon dioxide film accumulates by the low-temperature CVD (Chemical Vapor Deposition) method. When a thick silicon dioxide film is deposited with a CVD method, between narrow wirings, a silicon dioxide film will not fully turn, and, as a result, a cavity will occur between wirings.

[Patent Reference 1] Japanese Unexamined Patent Publication No. 2005-085903

[Patent Reference 2) Japanese Unexamined Patent Publication No. Hei 1-296641

### SUMMARY OF THE INVENTION

According to the technology of above-mentioned Patent Reference 2, in order that a cavity is produced between wirings, it is necessary to use an insulating film with bad step coverage nature, i.e., insulating film with many amounts of deposition to a plane part, and with few amounts of deposition to a wall part. In this case, while the plasma damage increased to this insulating film, the hydrogen content in a film did increase etc. and there was a problem of causing lowering of the reliability of elements, such as a memory cell.

The present invention is made in view of the above problems, and the purpose is to offer the semiconductor device whose reliability of an element is high, and which is hard to generate malfunction, and its manufacturing method.

The semiconductor device of 1 of the present invention is provided with a semiconductor substrate, a plurality of convex patterns, the first insulating layer, the second insulating layer, and the third insulating layer. Each of a plurality of convex patterns is formed on the front surface of a semiconductor substrate so that it may have a gate. The first insulating layer has covered the side surface and the upper surface of a plurality of convex patterns, and the bottom between convex patterns. The second insulating layer covers the cavity part located via the first insulating layer between a plurality of convex patterns and on a plurality of convex patterns, and has a through hole. The third insulating layer closes the through hole of the second insulating layer, and occludes the cavity part.

Other semiconductor device of the present invention is provided with a semiconductor substrate, a plurality of convex patterns, the first insulating layer, the second side wall-shaped insulating layer, and the third insulating layer. Each of a plurality of convex patterns is formed on the front surface of a semiconductor substrate so that it may have a gate. The first insulating layer has covered the side surface and the upper surface of a plurality of convex patterns, and the bottom between convex patterns. The second side wall-shaped insulating layer is formed on the cavity part located via the first insulating layer between a plurality of convex patterns and in the side wall of the first insulating layer. The third insulating layer is embedding between the second insulating layers so that a cavity part may be occluded.

A method of manufacturing a semiconductor device of the present invention comprises the steps of forming a plurality of convex patterns each of which has a gate over a front surface of a semiconductor substrate, forming a first insulating layer so that a side surface and an upper surface of the convex patterns, and a bottom between the convex patterns may be covered, forming an embedded layer so that between the convex patterns may be embedded, forming a second insulating layer over the embedded layer, forming in the second insulating layer a hole which reaches the embedded layer, removing the embedded layer by isotropic etching via the hole, and forming a cavity part between the convex patterns, and forming a third insulating layer so that the hole may be closed and the cavity part may be occluded.

According to the semiconductor device of the present invention, and its manufacturing method, after an embedded layer is formed between convex patterns, a cavity part is formed by doing etching removal of the embedded layer. Thus, since a cavity part is formed by etching, it is not necessary to form a film with bad step coverage nature like the case a cavity part is formed by film formation. For this reason, the reliability of an element can be increased rather than a conventional case, without a plasma damage increases to a film without the hydrogen content in a film increasing.

Since etching removal of the embedded layer is done via the hole formed in the second insulating layer, a cavity part can be easily occluded by closing a hole.

Since capacitance between gates can be made small by forming a cavity part between gates, malfunction can be made hard to generate.

### BRIEF DESCRIPTION OF THE DRAWINGS

FIG. 1 is a plan view showing roughly the structure of the semiconductor device in Embodiment 1 of the present invention;

FIG. 2A is an outline cross-sectional view which goes along the IIA-IIA line of FIG. 1, FIG. 2B is an outline cross-sectional view which goes along an IIB-IIB line, and FIG. 2C is an outline cross-sectional view which goes along an IIC-IIC line;

FIGS. 3A to 3C are outline cross-sectional views showing the first step of the manufacturing method of the semiconductor device in Embodiment 1 of the present invention;

FIGS. 4A to 4C are outline cross-sectional views showing the second step of the manufacturing method of the semiconductor device in Embodiment 1 of the present invention;

FIGS. 5A to 5C are outline cross-sectional views showing the third step of the manufacturing method of the semiconductor device in Embodiment 1 of the present invention;

FIGS. 6A to 6C are outline cross-sectional views showing the fourth step of the manufacturing method of the semiconductor device in Embodiment 1 of the present invention;

FIGS. 7A to 7C are outline cross-sectional views showing the fifth step of the manufacturing method of the semiconductor device in Embodiment 1 of the present invention;

FIGS. 8A to 8C are outline cross-sectional views showing the sixth step of the manufacturing method of the semiconductor device in Embodiment 1 of the present invention;

FIGS. 9A to 9C are outline cross-sectional views showing the seventh step of the manufacturing method of the semiconductor device in Embodiment 1 of the present invention;

FIGS. 10A to 10C are outline cross-sectional views showing the eighth step of the manufacturing method of the semiconductor device in Embodiment 1 of the present invention;

FIGS. 11A to 11C are outline cross-sectional views showing the ninth step of the manufacturing method of the semiconductor device in Embodiment 1 of the present invention;

FIGS. 12A to 12C are cross-sectional views showing roughly the structure of the semiconductor device in Embodiment 2 of the present invention, and FIG. 12A is an outline cross-sectional view corresponding to the section which goes along the IIA-IIA line of FIG. 1, FIG. 12B is an outline cross-sectional view corresponding to the section which goes along an IIB-IIB line, and FIG. 12C is an outline cross-sectional view corresponding to the section which goes along an IIC-IIC line;

FIGS. 13A to, 13C are outline cross-sectional views showing the first step of the manufacturing method of the semiconductor device in Embodiment 2 of the present invention;

FIGS. 14A to 14C are outline cross-sectional views showing the second step of the manufacturing method of the semiconductor device in Embodiment 2 of the present invention;

FIGS. 15A to 15C are outline cross-sectional views showing the third step of the manufacturing method of the semiconductor device in Embodiment 2 of the present invention;

FIGS. 16A to 16C are outline cross-sectional views showing the fourth step of the manufacturing method of the semiconductor device in Embodiment 2 of the present invention; and

FIGS. 17A to 17C are outline cross-sectional views showing the fifth step of the manufacturing method of the semiconductor device in Embodiment 2 of the present invention.

### DETAILED DESCRIPTION OF THE PREFERRED EMBODIMENTS

Hereafter, embodiments of the invention are explained based on drawings.

### (Embodiment 1)

A both-sides inversion layer type AG-AND type flash memory is mentioned as an example, and this embodiment explains it, for example.

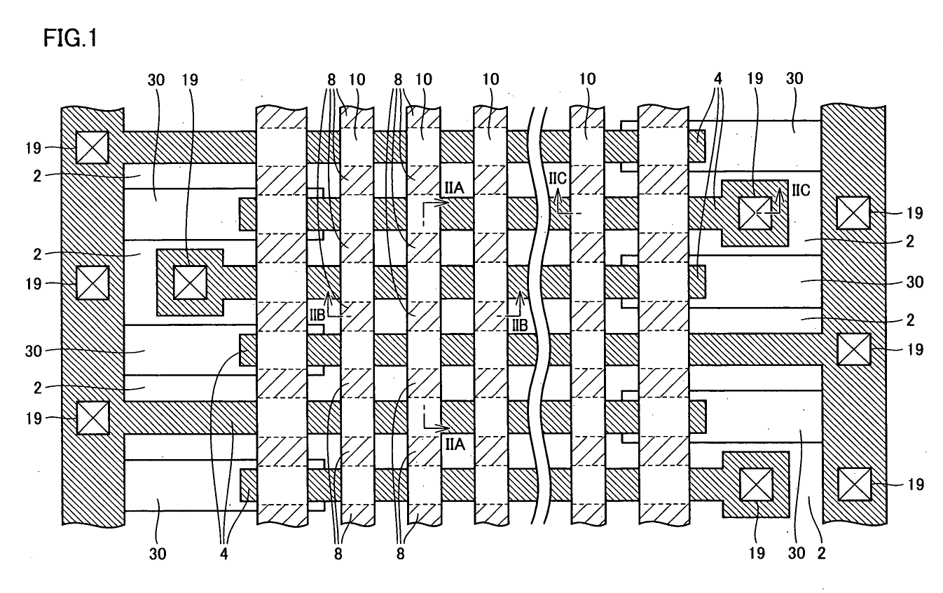

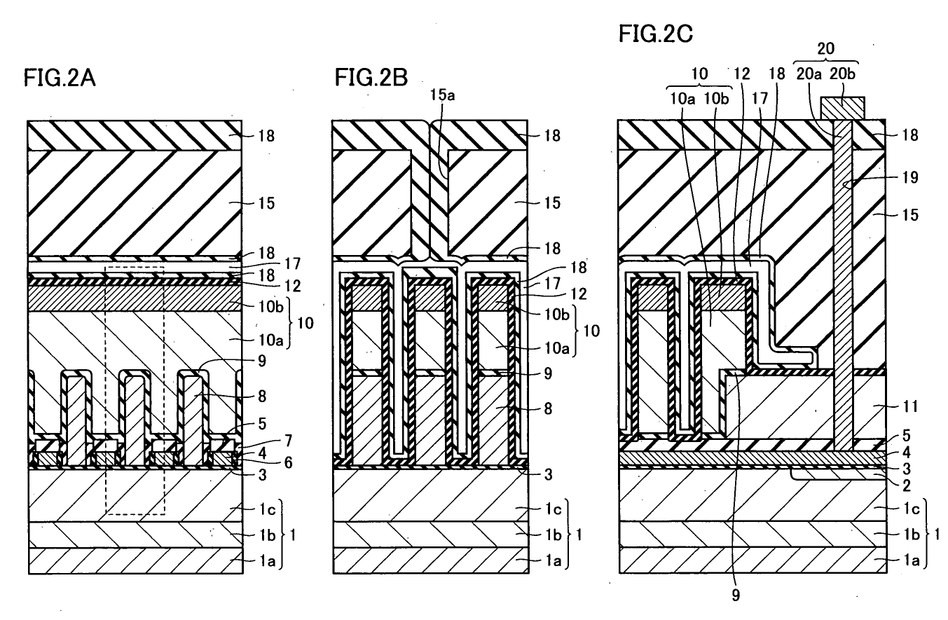

FIG. 1 is a plan view showing roughly the structure of the semiconductor device in Embodiment 1 of the present invention. FIGS. 2A, 2B, and 2C are outline cross-sectional views which go along the IIA-IIA line, IIB-IIB line, and IIC-IIC line of FIG. 1, respectively.

With reference to FIG. 1 mainly, isolation region 30 for electrically separating active region 2 is formed in the front surface of semiconductor substrate 1. On the memory cell array of this semiconductor substrate 1, it arranges so that each of a plurality of Assist Gate 4 may run in parallel mutually. It arranges so that it may intersect perpendicularly with this Assist Gate, and each of a plurality of control gates 10 may run in parallel mutually. Floating gate 8 is arranged in the region which is control gate 10 lower part and is inserted into Assist Gate 4.

Each of a plurality of Assist Gate 4 is electrically connected with the upper wiring layer 20b (refer to FIG. 2C) via contact hole 19.

With reference to FIG. 2A mainly, semiconductor substrate 1 has the structure by which p type region 1a, n type embedding region 1b, and p type well region 1c were laminated in order, for example. A plurality of memory cells are formed in this semiconductor substrate 1. Each of a plurality of memory cells mainly has one pair of Assist Gate 4 and 4, floating gate 8, and control gate 10. One memory cell is formed in the region enclosed with a dashed line among the drawing.

Each of one pair of Assist Gate 4 and 4 is formed via insulating layer 3 on the front surface of semiconductor substrate 1. Floating gate 8 is formed via gate insulating layer 3 on the front surface of semiconductor substrate 1 so that it may be inserted into one pair of Assist Gate 4 and 4. Control gate 10 is formed on floating gate 8 so that it may face via insulating layer 9 between gates with floating gate 8.

Each of Assist Gate 4 and floating gate 8 is formed from polycrystalline silicon of low resistance (polycrystalline silicon with which the impurity was doped), for example. Control gate 10 is formed by the laminated film of conductor film 10a which consists of polycrystalline silicon of low resistance, for example, and high melting point metal silicide films 10b, such as tungsten silicide (WSi_{X}) formed in the upper surface. Insulating layer 3 located under Assist Gate 4 consists of a silicon oxide film (SiO₂). Gate insulating layer 3 located under floating gate 8 functions as a tunnel insulating film of a memory cell, and consists of a silicon oxynitride film (SiON), a silicon oxide film, etc.

Insulating layer 5 and insulating layer 6 are formed in the upper surface and the side surface of Assist Gate 4, respectively, and insulating layer 7 is formed in them so that the side surface of the both sides of these insulating layers 5 and 6 may be covered. Insulating layer 5 consists of a silicon nitride film (Si₃N₄), and insulating layers 6 and 7 consist of a silicon oxide film, for example.

Cavity part (air gap) 17 is formed in the upper surface of control gate 10 via insulating layer 12 and insulating layer 18. On this cavity part 17, insulating layer 18, contact interlayer insulating layer 15, and insulating layer 18 are laminated and formed. Each of insulating layers 12 and 18 consists for example, of a TEOS (Tetra Ethyl Ortho Silicate) silicon oxide film. Contact interlayer insulating layer 15 consists of for example, the TEOS silicon oxide film, a plasma TEOS silicon oxide film, a BPSG (Boro-Phospho-Silicate Glass) film, etc.

With reference to FIG. 2B mainly, a plurality of convex patterns which laminate floating gate 8 and control gate 10 are formed in this section. The both sides of insulating layers (first insulating layer) 12 and 18 are formed so that the side surface and the upper surface of each of a plurality of convex patterns, and the bottom between convex patterns may be covered. Cavity part 17 is located via insulating layers 12 and 18 between a plurality of convex patterns and on a plurality of convex patterns. Contact interlayer insulating layer (second insulating layer) 15 covers cavity part 17, and has through hole 15a. Insulating layer (third insulating layer) 18 closes through hole 15a of contact interlayer insulating layer 15, and occludes cavity part 17.

With reference to FIG. 2C mainly, contact hole 19 penetrated insulating layers 5, 11, 12, 15, and 18, and has reached Assist Gate 4. Conductive layer 20 which consists of plug layer 20a which embeds the inside of this contact hole 19, and wiring layer 20b formed on insulating layer 18 so that it might connect with the plug layer 20a is electrically connected to Assist Gate 4.

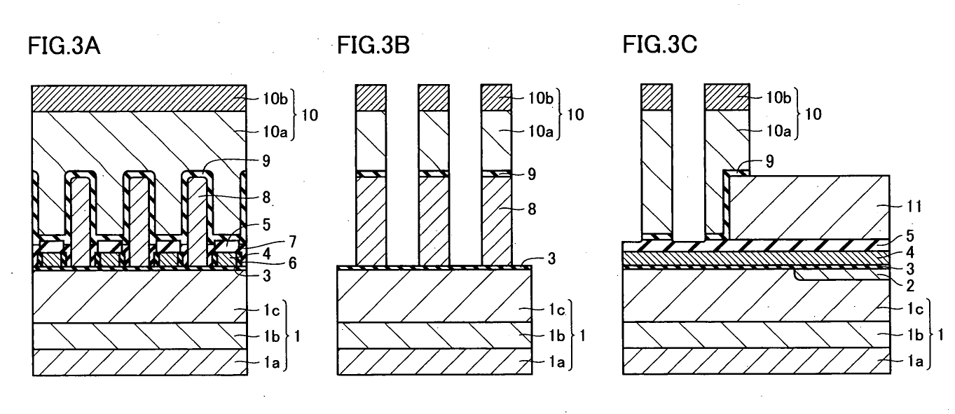

Next, the manufacturing method of the semiconductor device of this embodiment is explained. FIG. 3A-FIG. 11C are the outline cross-sectional views showing the manufacturing method of the semiconductor device in Embodiment 1 of the present invention at process order. With reference to FIGS. 3A to 3C, etching is performed by using control gate (word line) 10 as a mask by the usual manufacturing flow in floating gate 8 in a memory cell array. The lamination gate (convex pattern) of a memory cell is formed on the front surface of semiconductor substrate 1.

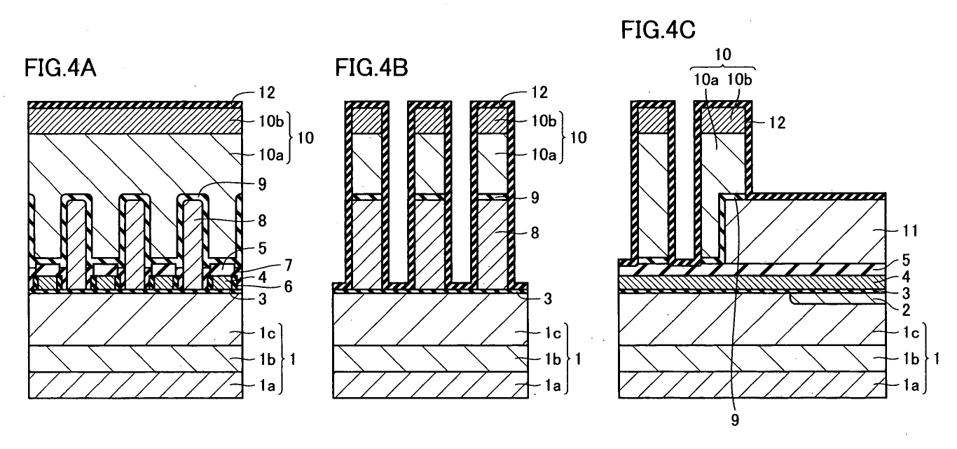

With reference to FIGS. 4A to 4C, insulating layer (first insulating layer) 12 is formed so that the upper surface and the side surface of this convex pattern, and the bottom between convex patterns may be covered. This insulating layer 12 is formed by depositing a TEOS silicon oxide film by the CVD (Chemical Vapor Deposition) method, for example. Insulating layer 12 is deposited in thickness as for which a clearance for polycrystalline silicon to enter between floating gates 8, for example, clearance of the width which is about 10 nm, is vacant, after depositing insulating layer 12.

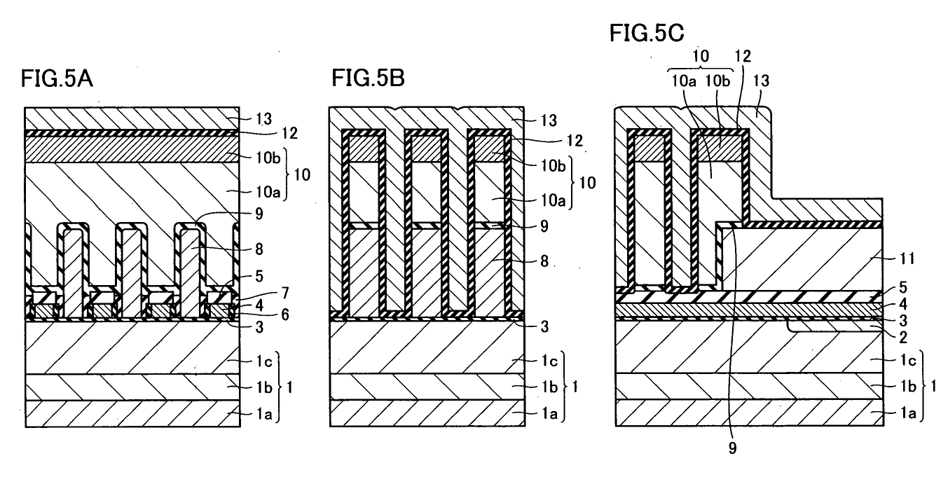

With reference to FIGS. 5A to 5C, polycrystalline silicon layer (embedded layer) 13 accumulates in the thickness of the grade which fills the above-mentioned clearance, and becomes flat in the control gate 10 upper part. What is necessary is just to deposit polycrystalline silicon layer 13 of a thickness of 10 nm or more, and 100 nm or less, when the width of the above-mentioned clearance is 10 nm, and the height of control gate 10 is 200 nm.

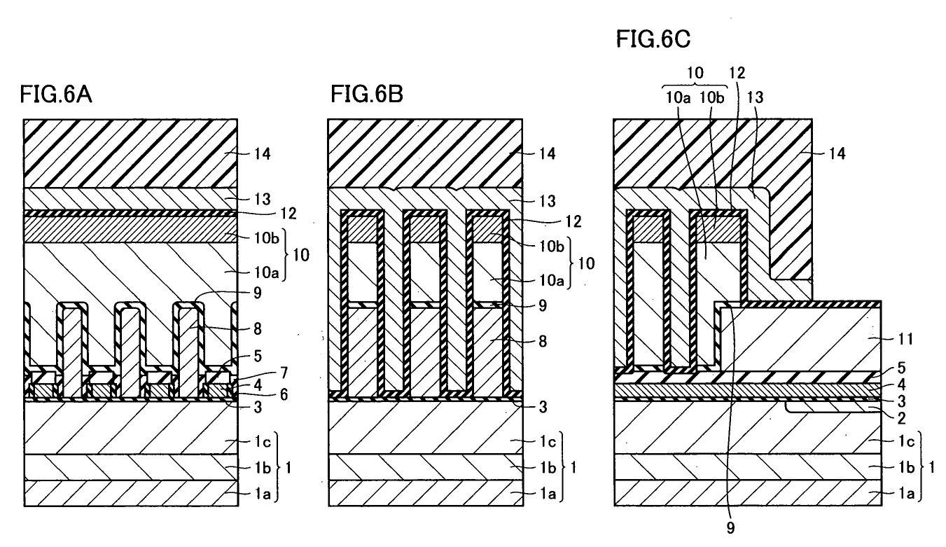

With reference to FIGS. 6A to 6C, photoresist 14 is applied on polycrystalline silicon layer 13, and it is exposed and developed by the usual photolithography process technology. Hereby, patterned resist pattern 14 is formed. By etching by using this resist pattern 14 as a mask, it is patterned so that polycrystalline silicon layer 13 may remain only in the memory cell array upper part. Then, resist pattern 14 is removed by ashing etc.

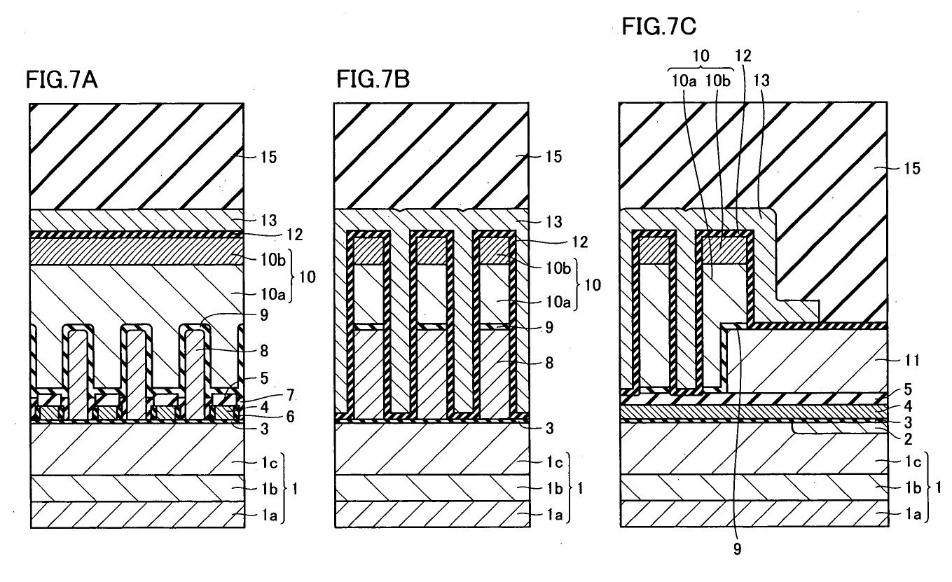

Using TEOS or plasma TEOS or BPSG etc., on a convex pattern, contact interlayer insulating layer (second insulating layer) 15 is formed via insulating layer 12 and polycrystalline silicon layer 13 with reference to FIGS. 7A to 7C. As long as a problem is in the flatness of the upper surface of contact interlayer insulating layer 15 at this time, flattening of the upper surface of contact interlayer insulating layer 15 may be performed using a CMP (Chemical Mechanical Polishing) process.

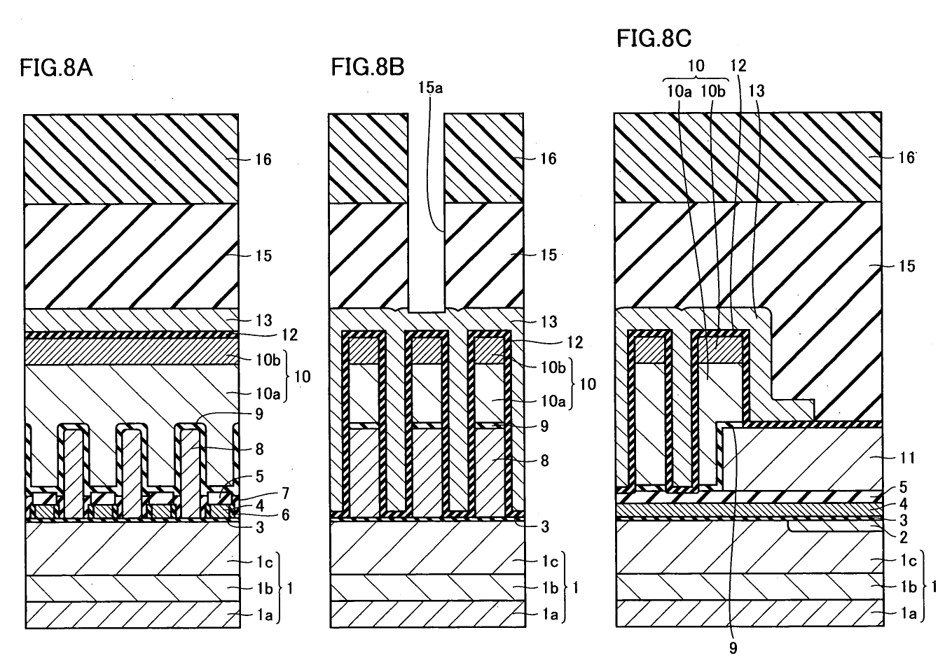

With reference to FIGS. 8A to 8C, photoresist 16 is applied on contact interlayer insulating layer 15, and it is exposed and developed by the usual photolithography process technology. Hereby, patterned resist pattern 16 is formed. By etching by using this resist pattern 16 as a mask, an opening of through hole 15a of the dummy which reaches polycrystalline silicon layer 13 is made in contact interlayer insulating layer 15. Then, resist pattern 16 is removed by ashing etc. Isotropic etching is performed to polycrystalline silicon layer 13 exposed from through hole 15a on conditions with the selectivity of polycrystalline silicon and a silicon oxide film after this.

As conditions for the above-mentioned etching, the isotropic plasma etching which was shown, for example in the following literature and which used SF₆ gas as the base may be used. The wet etching using the mixed solution (NH₄OH+H₂O₂+H₂O:APM) of ammonia and a hydrogen peroxide solution may be used. The wet etching using the mixed solution of fluoric acid, nitric acid, and a hydrogen peroxide solution may be used.

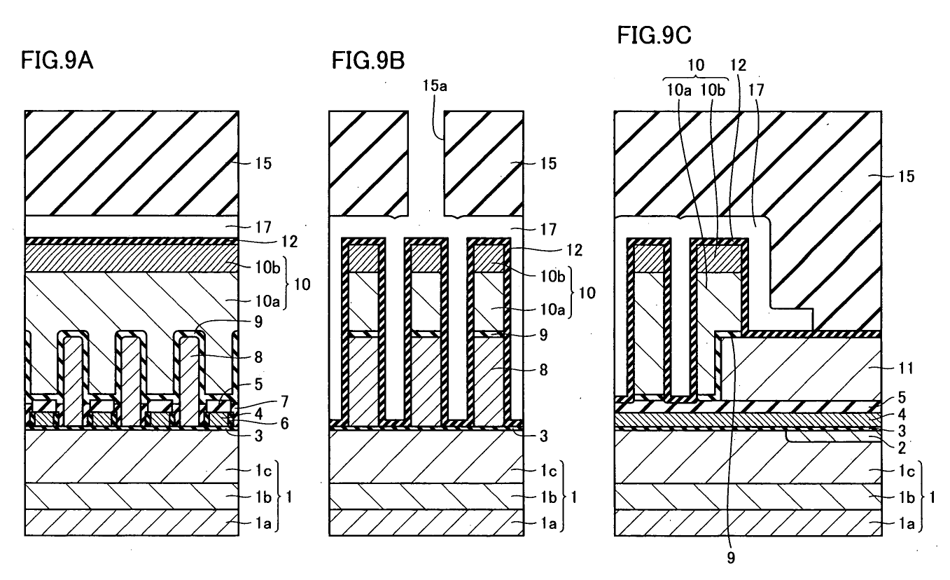

Literature: S. Harrison et al., “Poly-gate REplacement Through Contact Hole (PRETCH): A new method for High-K/Metal gate and multi-oxide implementation on chip”, IEDM Tech.Dig., December 2004, pp. 291-294. With reference to FIGS. 9A to 9C, polycrystalline silicon layer 13 is removed nearly thoroughly by the above-mentioned etching, and cavity part 17 is formed between the convex patterns and on a convex pattern in whole memory cell array upper part. A plurality of through holes 15a may be formed although one is shown for the facilities of explanation.

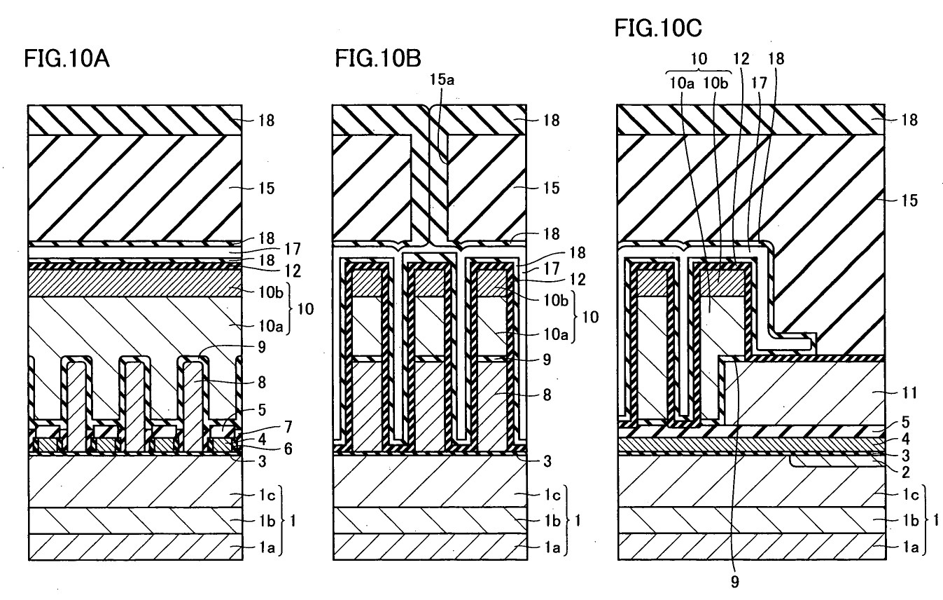

In order to fill dummy through hole 15a and to make cavity part 17 occluded with reference to FIGS. 10A to 10C, insulating layer 18 (third insulating layer) with a little bad step coverage nature is stacked and added, and it deposits as a contact interlayer film. At this time, the step coverage nature for which insulating layer 18 is asked is decided by the hole size and the depth of dummy through hole 15a. It is unnecessary in the badness of step coverage nature as the aspect ratio (depth/hole size) of through hole 15a becomes high. For example, when the hole size of through hole 15a is 200 nm, and the depth is 500 nm, and depositing about 150 nm of insulating layers 18 with the CVD method using TEOS, dummy through hole 15a is occluded sufficiently.

At this time, also in cavity part 17, insulating layer 18 is formed a little so that the front surface of insulating layer 12 and contact interlayer insulating layer 15 may be covered. However, when the hole size of dummy through hole 15a is small, through hole 15a occludes previously. Therefore, the particularly important region between floating gates 8 in cavity part 17 is not closed by insulating layer 18. In other words, it is necessary to choose the depth and the hole size of dummy through hole 15a, and the step coverage nature at the time of insulating layer 18 film formation so that cavity part 17 between floating gates 8 has not been again buried with insulating layer 18 before occluding through hole 15a.

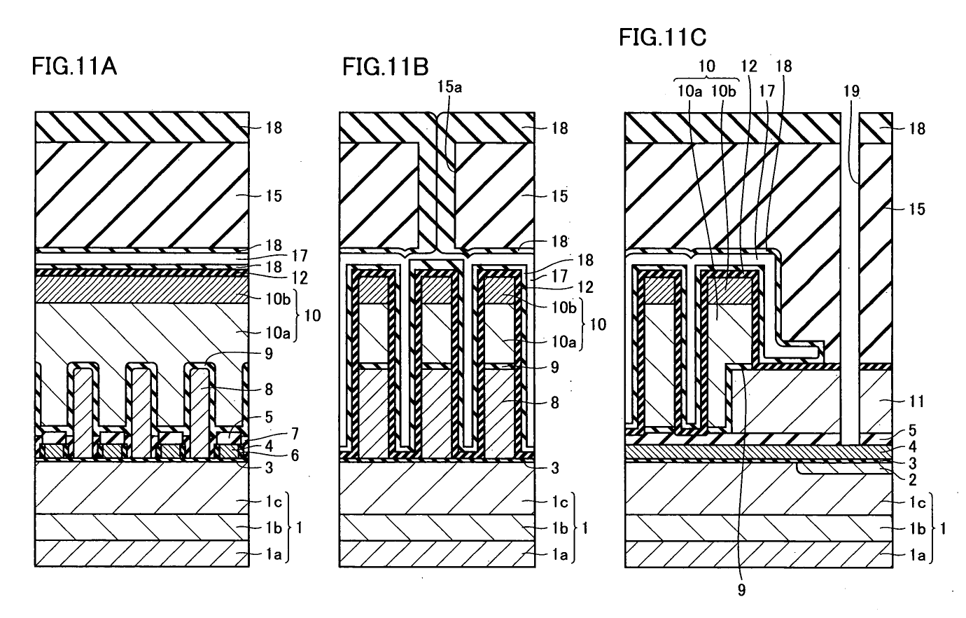

With reference to FIGS. 11A to 11C, contact hole 19 which penetrates each of insulating layers 18, 15, 12, 11, and 5, and reaches Assist Gate 4 is formed using usual photolithography process technology and etching technology.

With reference to FIGS. 2A to 2C, plug layer 20a is formed so that contact hole 19 may be embedded, and wiring layer 20b is formed so that it may connect with this plug layer 20a. Hereby, the semiconductor device of this embodiment is manufactured. Since the next step is the same as the process of the usual lamination wiring structure, the explanation is omitted.

According to this embodiment, as shown in FIG. 8 and FIG. 9, polycrystalline silicon layer 13 is formed between the convex patterns with which it comes to laminate floating gate 8 and control gate 10. After that, cavity part 17 is formed by doing etching removal of the polycrystalline silicon layer 13. Thus, since cavity part 17 is formed by etching, it is not necessary to form a film with bad step coverage nature like the case cavity part 17 is formed by film formation. For this reason, the plasma damage at the time of forming a film with bad step coverage nature does not increase. The reliability of an element can be increased rather than a conventional case, without the hydrogen content in a film increasing.

Etching removal of the polycrystalline silicon layer 13 can be done via through hole 15a formed in contact interlayer insulating layer 15, and cavity part 17 can be easily occluded by closing the through hole 15a.

By forming cavity part 17 between floating gates 8, parasitic capacitance between floating gates 8 can be made small. For this reason, change of the charge quantity accumulated into the floating gate of the selected memory cell can be suppressed in the case of read operation. Therefore, the so-called threshold value voltage Vth shift to which the threshold value voltage of the selected memory cell is changed can be reduced, and malfunction can be made hard to generate.

Standup delay of word line 10 at the time of the writing, erasure, and a read of a memory cell can also be made small.

As mentioned above, the depth and the hole size of dummy through hole 15a, and the step coverage nature at the time of insulating layer 18 film formation are chosen appropriately. Hereby, even if it occludes through hole 15a, thickness of insulating layer 18 deposited in cavity part 17 can be made into few amounts. For this reason, the influence insulating layer 18 in this cavity part 17 has on the size of cavity part 17 and reliability degradation of a memory cell is also small.

### (Embodiment 2)

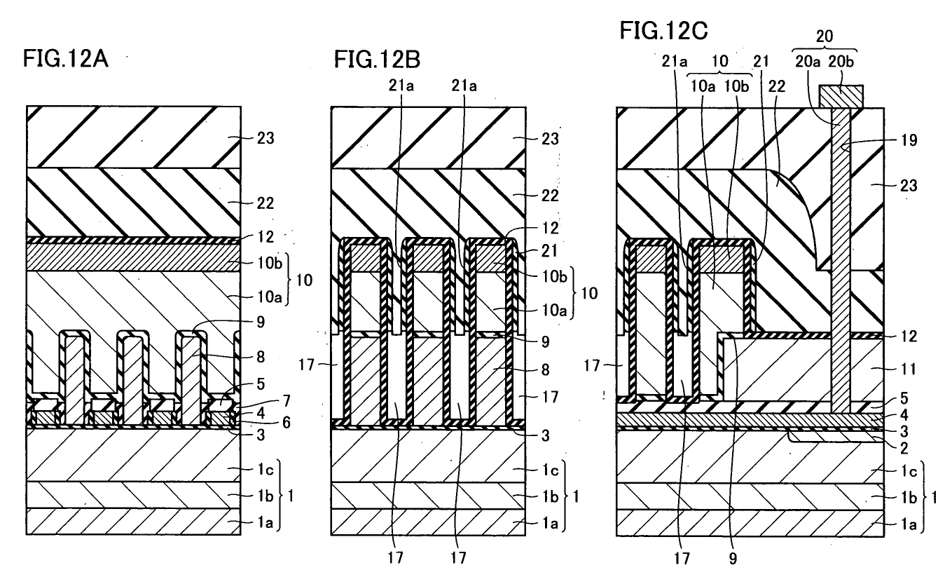

FIGS. 12A, 12B, and 12C are the cross-sectional views showing roughly the structure of the semiconductor device in Embodiment 2 of the present invention, and are an outline cross-sectional view corresponding to the section which goes along the IIA-IIA line, IIB-IIB line, and IIC-IIC line of FIG. 1, respectively. With reference to FIGS. 12A to 12C, the structures of this embodiment mainly differ about the structure of cavity part 17 as compared with the structure of Embodiment 1.

In this embodiment, cavity part 17 is located between the convex patterns which consist of lamination of floating gate 8 and control gate 10, and is formed in the side part of the convex pattern via insulating layer (first insulating layer) 12. This cavity part 17 is formed only between floating gates 8, and is not formed in the side part and the upper part of control gate 10. Side wall-shaped insulating layer (second insulating layer) 21 is formed on cavity part 17 and in the side wall of insulating layer 12. Through hole 21a is formed between this insulating layer 21. Insulating layer (third insulating layer) 22 is formed so that through hole 21a between this insulating layer 21 may be embedded and cavity part 17 may be occluded. Insulating layer 23 is formed on this insulating layer 22.

Contact hole 19 penetrated insulating layers 5, 11, 12, 22, and 23, and has reached Assist Gate 4. Conductive layer 20 which consists of plug layer 20a which embeds the inside of this contact hole 19, and wiring layer 20b formed on insulating layer 23 so that it might connect with the plug layer 20a is electrically connected to Assist Gate 4.

Since it is almost the same as the structure of Embodiment 1 mentioned above about structures other than the above, the same reference is attached about the element which is the same or corresponds, and the explanation is omitted.

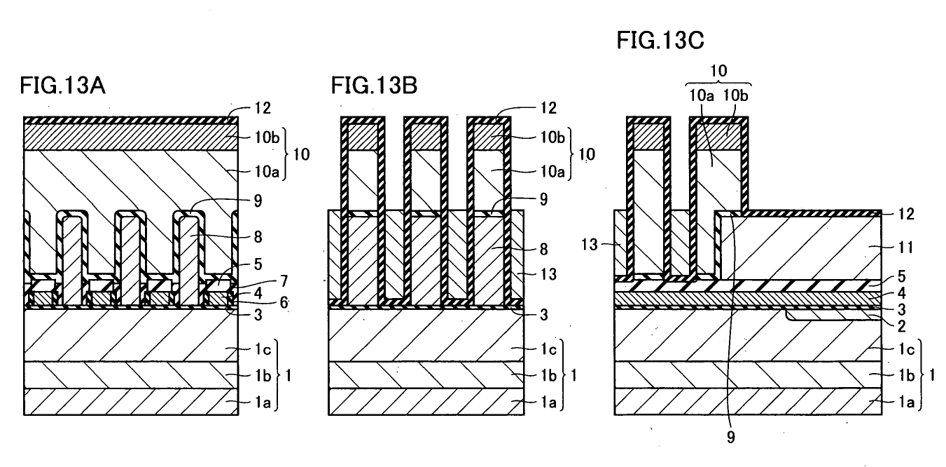

Next, the manufacturing method of the semiconductor device of this embodiment is explained. FIG. 13A-FIG. 17C are the outline cross-sectional views showing the manufacturing method of the semiconductor device in Embodiment 2 of the present invention at process order. The manufacturing method of this embodiment passes through the same step as the step of Embodiment 1 shown in FIG. 3A-FIG. 5C. Then, an etch back is given to polycrystalline silicon layer 13.

While the upper surface, and the portion of a side surface of insulating layer (first insulating layer) 12 is exposed with reference to FIG. 13 with the above-mentioned etch back, polycrystalline silicon layer (embedded layer) 13 remains at a bottom between convex patterns, and between floating gates 8.

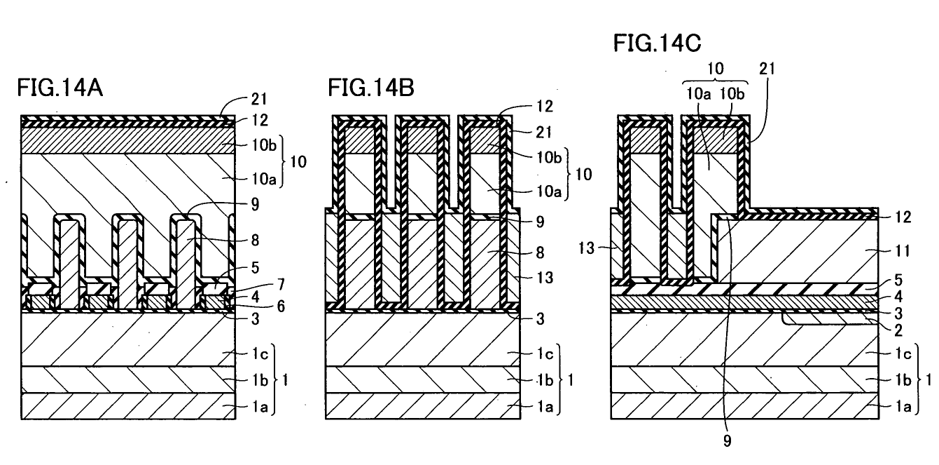

With reference to FIGS. 14A to 14C, a TEOS silicon oxide film is formed, for example by a CVD method as insulating layer 21 so that the exposed upper surface of polycrystalline silicon layer 13, and the exposed upper surface and the side surface of insulating layer 12 may be covered. Then, the etch back of anisotropy is given to insulating layer 21 until the upper surface of insulating layer 12 is exposed.

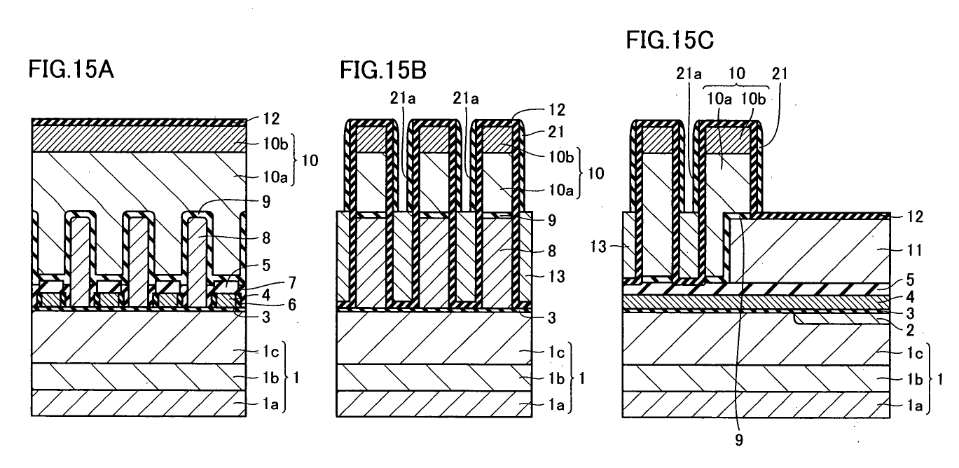

While insulating layer (second insulating layer) 21 of the side wall form which covers the side wall of insulating layer 12 is formed on polycrystalline silicon layer 13 with the above-mentioned etch back with reference to FIGS. 15A to 15C, between insulating layers 21, through hole 21a which reaches the front surface of polycrystalline silicon layer 13 is formed. The gap of insulating layer 21 in this through hole 21a is set to 20 nm or less and 5 nm or more.

Then, isotropic etching is performed to polycrystalline silicon layer 13 exposed from through hole 21a on conditions with the selectivity of polycrystalline silicon and a silicon oxide film. The isotropic plasma etching which was shown, for example in the above-mentioned literature as conditions for this etching and which used SF₆ gas as the base may be used. The wet etching using the mixed solution (NH₄OH+H₂O₂+H₂O:APM) of ammonia and a hydrogen peroxide solution may be used. The wet etching using the mixed solution of fluoric acid, nitric acid, and a hydrogen peroxide solution may be used.

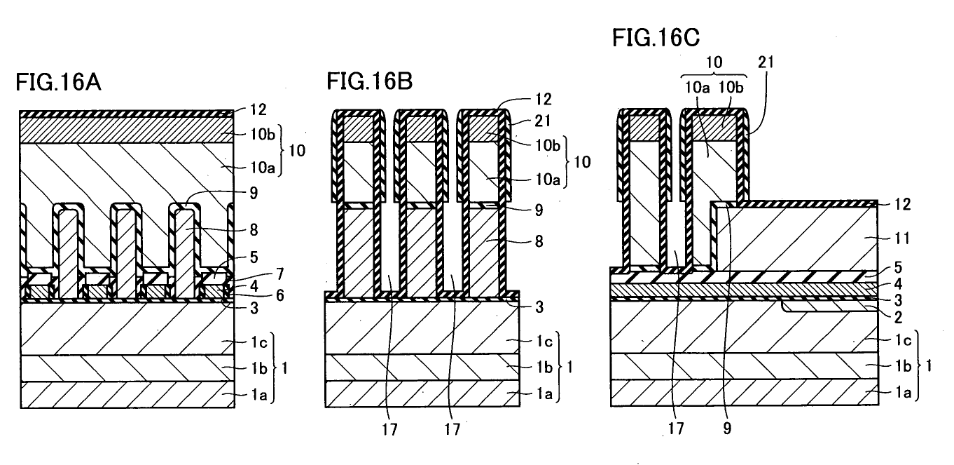

With reference to FIGS. 16A to 16C, by the above-mentioned etching, polycrystalline silicon layer 13 is removed nearly thoroughly, and cavity part 17 is formed between floating gates 8.

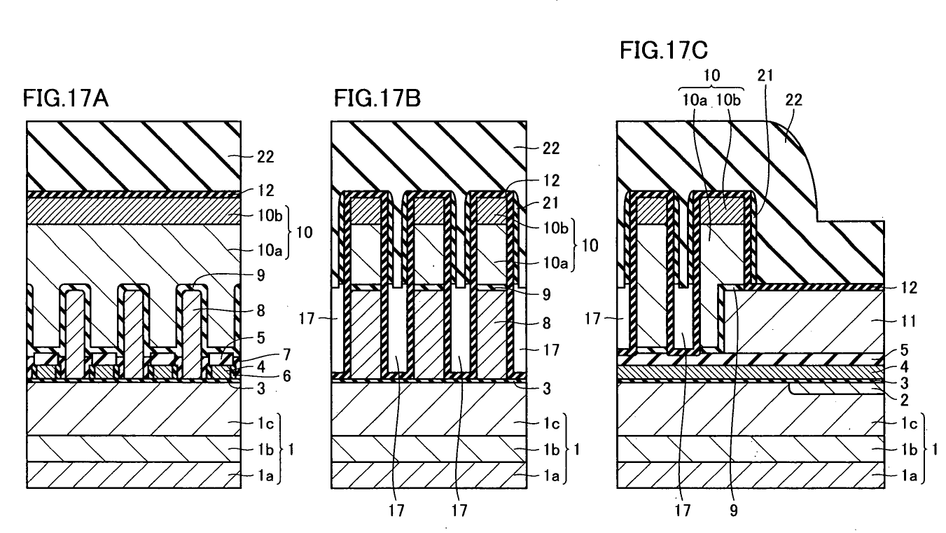

In order to fill this through hole 21a and to make cavity part 17 occluded with reference to FIGS. 17A to 17C, insulating layer 22 with a little bad step coverage nature (third insulating layer) is deposited as a gap choking film. At this time, the step coverage nature for which insulating layer 22 is asked is decided by the hole size and the depth of through hole 21a. It is unnecessary in the badness of step coverage nature as the aspect ratio (the depth/hole size) of through hole 21a becomes high. For example, when the hole size of through hole 21a is 20 nm, the depth is 200 nm and about 50 nm of insulating layers 22 will be deposited with the CVD method using TEOS, through hole 21a is occluded sufficiently.

Insulating layer 22 is formed a little also in cavity part 17 between floating gates 8 at this time. However, the inside of cavity part 17 between floating gates 8 is not closed by insulating layer 22, since through hole 21a occludes previously when the hole size of through hole 21a is small. In other words, it is necessary to choose the depth and the hole size of through hole 21a, and the step coverage nature at the time of insulating layer 22 film formation so that cavity part 17 between floating gates 8 has not been again buried with insulating layer 22 before occluding through hole 21a.

With reference to FIGS. 12A to 12C, insulating layer 23 is formed as a contact interlayer film on insulating layer 22. Flattening processing is performed according to need to the upper surface of insulating layer 23. Then, contact hole 19 which penetrates each of insulating layers 23, 22, 12, 11, and 5, and reaches Assist Gate 4 is formed using usual photolithography process technology and etching technology. Plug layer 20a is formed so that this contact hole 19 may be embedded, and wiring layer 20b is patterned and formed so that it may connect with this plug layer 20a. Hereby, the semiconductor device of this embodiment is manufactured. Since the next step is the same as the process of the usual lamination wiring structure, the explanation is omitted.

According to this embodiment, as shown in FIGS. 15A to 15C and FIGS. 16A to 16C, polycrystalline silicon layer 13 is formed between the convex patterns in which floating gate 8 and control gate 10 are laminated, and become. After that, cavity part 17 is formed by doing etching removal of the polycrystalline silicon layer 13. Thus, since cavity part 17 is formed by etching, it is not necessary to form a film with bad step coverage nature like the case cavity part 17 is formed by film formation. For this reason, the plasma damage at the time of forming a film with bad step coverage nature does not increase. The reliability of an element can be increased rather than a conventional case, without the hydrogen content in a film increasing.

Since etching removal of the polycrystalline silicon layer 13 is done via through hole 21a formed in insulating layer 21, cavity part 17 can be easily occluded by closing the through hole 21a.

By forming cavity part 17 between floating gates 8, parasitic capacitance between floating gates 8 can be made small. For this reason, change of the charge quantity accumulated into the floating gate of the selected memory cell can be suppressed in the case of read operation. Therefore, the so-called threshold value voltage Vth shift to which the threshold value voltage of the selected memory cell is changed can be reduced, and malfunction can be made hard to generate.

Standup delay of word line 10 at the time of the writing, erasure, and a read of a memory cell can also be made small.

As mentioned above, even if it occludes through hole 21a, by choosing appropriately the depth and the hole size of through hole 21a, and the step coverage nature at the time of insulating layer 22 film formation, thickness of insulating layer 22 deposited in cavity part 17 can be made into few amounts. For this reason, the influence insulating layer 22 in this cavity part 17 has on the size of cavity part 17 and reliability degradation of a memory cell is also small.

As compared with Embodiment 1, it is unnecessary in the opening process of dummy through hole 15a. The structure of having a cavity part is realizable, securing the reliability of a cell in a cheap process easily.

In above-mentioned Embodiment 2, the both-sides inversion layer type AG-AND type flash memory was mentioned as the example, and was explained. However, the present invention is not limited to this. Also in a NAND type flash memory structure which does not have contact into a memory cell array, and a one-sided inversion layer type AG-AND type flash memory structure, the above-mentioned structure is realizable in the almost same process. It is applicable to the element structure provided with the convex pattern which has a gate besides this.

It should be thought that the embodiment disclosed this time is exemplification at all points, and not restrictive. The range of the present invention is shown by not the above-mentioned explanation but the claim. It is meant that all the change in an equivalent meaning and the equivalent range to a claim is included.

The present invention may be applied especially in favor of the semiconductor device which has a cavity part between gates, and its manufacturing method.

What is claimed is:

1. A semiconductor device, comprising:
a semiconductor substrate;
a plurality of convex patterns formed over a front surface of the semiconductor substrate so that each might have a gate;
a first insulating layer that covers a side surface and an upper surface of the convex patterns, and a bottom between the convex patterns;
a second insulating layer that covers a cavity part located via the first insulating layer between the convex patterns and over the convex patterns, and has a through hole; and
a third insulating layer that closes a through hole of the second insulating layer, and occludes the cavity part.

2. A semiconductor device, comprising:
a semiconductor substrate;
a plurality of convex patterns formed over a front surface of the semiconductor substrate so that each might have a gate;
a first insulating layer that covers a side surface and an upper surface of the convex patterns, and a bottom between the convex patterns;
a second insulating layer of a side wall form which was formed over a cavity part located via the first insulating layer between the convex patterns, and in a side wall of the first insulating layer; and
a third insulating layer that embeds between the second insulating layers so that the cavity part may be occluded.

3. A semiconductor device according to claim 1, wherein
the gate has a floating gate and a control gate which were laminated mutually.

4. A semiconductor device according to claim 3, further comprising:
an assist gate extending and existing in a direction which intersects the control gate in a plane pattern.

5. A method of manufacturing a semiconductor device, comprising the steps of:
forming a plurality of convex patterns each of which has a gate over a front surface of a semiconductor substrate;
forming a first insulating layer so that a side surface and an upper surface of the convex patterns, and a bottom between the convex patterns may be covered;
forming an embedded layer so that between the convex patterns may be embedded;
forming a second insulating layer over the embedded layer;
forming in the second insulating layer a hole which reaches the embedded layer;
removing the embedded layer by isotropic etching via the hole, and forming a cavity part between the convex patterns; and
forming a third insulating layer so that the hole may be closed and the cavity part may be occluded.

6. A method of manufacturing a semiconductor device according to claim 5, wherein
the embedded layer is formed so that between the convex patterns may be embedded and it may be located also over the convex patterns; and
the second insulating layer is formed via the first insulating layer and the embedded layer over the convex pattern.

7. A method of manufacturing a semiconductor device according to claim 5, wherein
the step of forming the embedded layer includes the steps of:
forming the embedded layer so that between the convex patterns may be embedded and it may be located also over the convex patterns; and
removing the embedded layer until an upper surface, and a portion of a side surface of the first insulating layer is exposed;
wherein
the second insulating layer is formed over the embedded layer which remained at a bottom between the convex patterns.

8. A method of manufacturing a semiconductor device according to claim 7, wherein
the step of forming the hole in the second insulating layer includes the steps of:
forming the second insulating layer so that an upper surface and a side surface of the first insulating layer which were exposed may be covered; and
making the second insulating layer remain in a side wall form which covers a side wall of the first insulating layer, and forming in the second insulating layer the hole which reaches the embedded layer by performing anisotropic etching to the second insulating layer until an upper surface of the first insulating layer is exposed.
